(19) United States
(12) Patent Application Publication
(10) Pub. No.: US 2019/0115487 A1
(43) Pub. Date: Apr. 18, 2019

(54) PEROVSKITE SOLAR CELL MODULE AND FABRICATION METHOD THEREOF

(71) Applicant: CPC Corporation, Taiwan, Kaohsiung City (TW)

(72) Inventor: Kuan-Chieh HUANG, Kaohsiung City (TW)

(21) Appl. No.: 15/849,133

(22) Filed: Dec. 20, 2017

(30) Foreign Application Priority Data
Oct. 18, 2017 (TW) 106135737

(51) Int. Cl. H01L 31/0468; H01L 31/048; H01L 31/0392; H01L 51/44; H01G 9/20; H01L 31/05

(52) U.S. Cl. CPC H01L 31/0468; H01L 31/0488; H01L 31/0504; H01L 51/448; H01G 9/20; H01L 31/0392

(57) ABSTRACT

The present invention provides a perovskite solar cell module including: a light-transparent substrate, a plurality of solar cells, a plurality of insulating units, and a plurality of connecting units. Each solar cell is constituted by a transparent conductive layer, a first carrier conducting layer, a perovskite layer, and a second carrier conducting layer. By changing the ratio of area where the light is harvested for the perovskite layer, the photon absorption in the present invention therefore increases. Additionally, by changing the relevant position of the transparent conductive layer and the first carrier conducting layer, it renders the side surface of the transparent conductive layer be entirely covered by the first carrier conducting layer; thus, the usage of carriers is enhanced. The above two adoptions further enhance the efficiency of the module. Moreover, the insulating units are in the structure of distributed Bragg reflection and therefore can increase the photon absorption efficiency of the perovskite layer. Last but not least, the present invention further accomplishes the goal to manufacture a large-area perovskite solar cell module in order to meet the commercial demand.

### CROSS-REFERENCE TO RELATED APPLICATIONS

This Non-provisional application claims priority under 35 U.S.C. § 119(a) on Patent Application No(s). 106135737 filed in Taiwan, Republic of China, on Oct. 18th, 2017; the entire contents of which are hereby incorporated by reference.

### FIELD OF THE INVENTION

The invention relates to a perovskite solar cell module and a manufacturing process of the same; in particular, a perovskite solar cell module and a manufacturing process of the same which photon absorption area can be increased.

### BACKGROUND OF THE INVENTION

Solar power is considered to be one of the efficient ways to resolve the issues of insufficient energy and global warming. After decades, solar power has been evolving from amorphous silicon (a-Si) solar cells to various types of solar cells, such as thin-film solar cells, organic solar cells, and dye sensitized solar cells, et cetera. Perovskite solar cells, built based upon dye sensitized solar cells, on the other hand, have gained many attentions in the recent years because of their high photovoltaic conversion efficiency.

Many institutions have been putting efforts on the research and development of perovskite solar cells, lots of improvements have been made to its efficiency as well as the structure and the manufacturing process. In 2014, the team at UCLA led by Professor Yang Yang successfully produced a perovskite solar cell with efficiency of 19.3% by controlling the growth of the relevant perovskite thin film at low temperature (below 150° C.). However, its active area is merely 0.1 cm² and the open circuit voltage is 1.13 V. A conventional perovskite solar cell has relatively small active area (less than 0.2 cm²) and low open circuit voltage (around 1.0 V) which makes it difficult to drive any electronic device on its own. Moreover, when the cells are cascade-connected, the adoption of techniques such as manual bridging and laser scribing will complicate the manufacturing process.

The inventor of the present invention proposed the Taiwan Patent 1553892 titled “Solar Cell Module Having Perovskite Donor Layer.” The invention discloses a method to resolve the issues of insufficient voltage and high resistance by serially bridging the connecting units and electrically connecting to the solar cells. Despite the structure has been able to resolve some issues, there is room for the improvement of efficiency. Given that, the inventor hereby proposes a perovskite solar cell module and manufacturing process of the same. The advantages of the present solution are well documented. It can not only increase the light absorption area as well as the efficiency of the module, but also accomplish the goal to manufacture a large-area perovskite solar cell module to meet the commercial demand.

### SUMMARY OF THE INVENTION

Given the above mentioned problems, the present invention discloses a perovskite solar cell module and fabrication method of the same.

The perovskite solar cell module of the present invention includes a light-transparent substrate having an upper surface and a lower surface where the light incidents through the lower surface; a plurality of solar cells formed on the light-transparent substrate, each of the solar cells further includes: a transparent conductive layer disposed on the upper surface of the light-transparent substrate; a first carrier conducting layer disposed on the transparent conductive layer, wherein the first carrier conducting layer partially covers an upper surface of the transparent conductive layer and entirely covers the side surface of the transparent conductive layer, wherein the first carrier conducting layer contacts with the upper surface of the light-transparent substrate; a perovskite layer disposed on the first carrier conducting layer; and a second carrier conducting layer disposed on the perovskite layer; a plurality of insulating units disposed on the second carrier conducting layer of each solar cell, wherein each insulting unit extends to cover the side surfaces of the second carrier conducting layer, the perovskite layer and the first carrier conducting layer of each solar cell, wherein each insulating unit forms a first channel with the upper space of the transparent conductive layer of each solar cell, and forms a second channel with the second carrier conducting layer of each solar cell; and a plurality of connecting units disposed above the second carrier conducting layer of each solar cell, wherein each of the connecting units electronically connects one solar cell to another through the first channel and the second channel, wherein there remains a gap between two adjacent connecting units.

The method of manufacturing a perovskite solar cell module having a plurality of solar cells of the present invention includes: providing a light-transparent substrate; forming a plurality of transparent conductive layers on the light-transparent substrate; forming a first carrier conducting layer on the transparent conductive layer, wherein the first carrier conducting layer covers the side surface of the transparent conductive layers entirely, wherein the first carrier conducting layer further contacts with an upper surface of the light-transparent substrate; forming a perovskite layer on the first carrier conducting layer; forming a second carrier conducting layer on the perovskite layer; forming a plurality of first channels, wherein the first channels extend upwardly from the upper surface of the transparent conductive layers to the second carrier conducting layer, wherein the first channels define and isolate the transparent conductive layer, the first carrier conducting layer, the perovskite layer and the second carrier conducting layer into the solar cells; forming a plurality of insulating units on the second carrier conducting layer, wherein the insulating units extend to cover the side surfaces of the second carrier conducting layer, the perovskite layer, and the first carrier conducting layer within the first channels, wherein the insulating units further form a second channel with an upper space of the second carrier conducting layer; and forming a plurality of connecting units above the second carrier conducting layer, the connecting units electronically connect one solar cell to another solar cell through the first channels and the second channels, wherein there is a gap between two adjacent connecting units.

In the present invention, by changing the ratio of area where the light is harvested for the perovskite layer, the photon absorption can therefore be increased. Additionally, by changing the relevant position of the transparent conductive layer and the first carrier conducting layer, the side surface of the transparent conductive layer can be entirely covered by the first carrier conducting layer, as a result, the usage of carriers is enhanced. The combination of the two above adoptions increases the module's overall efficiency. Moreover, the structure of distributed Bragg reflection is adopted as well as the insulating units to increase the photon absorption efficiency of the perovskite layer. Last but not least, the present invention further accomplishes the goal to manufacture a large-area perovskite solar cell module to meet the commercial demand.

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be discussed below.

### BRIEF DESCRIPTION OF THE DRAWINGS

FIG. 1 is a cross-section view of a perovskite solar cell module in accordance with one of the embodiments of the present invention;

FIG. 2 is a cross-section view of distributed Bragg reflection of the present invention;

FIG. 3 is a cross-section view of a perovskite solar cell module in accordance with another of the embodiments of the present invention;

FIG. 4(A) is a top view of a perovskite solar cell module in accordance with one of the embodiments of the present invention;

FIG. 4(B) is a cross-section view of a perovskite solar cell module in accordance with the embodiment illustrated in FIG. 4(A);

FIGS. 5-12 demonstrate the method for preparing and manufacturing a perovskite solar cell module in accordance with the present invention;

FIG. 13 shows experimental data of the present perovskite solar cell module.

### DETAILED DESCRIPTION OF THE INVENTION

Various aspects are now described with reference to the drawings. In the following description, for purposes of explanation, numerous specific details are set forth in order to provide a thorough understanding of one or more aspects. It may be evident, however, that the various aspects may be practiced without these specific details. In other instances, well-known structures and devices are shown in block diagram form in order to facilitate describing these aspects.

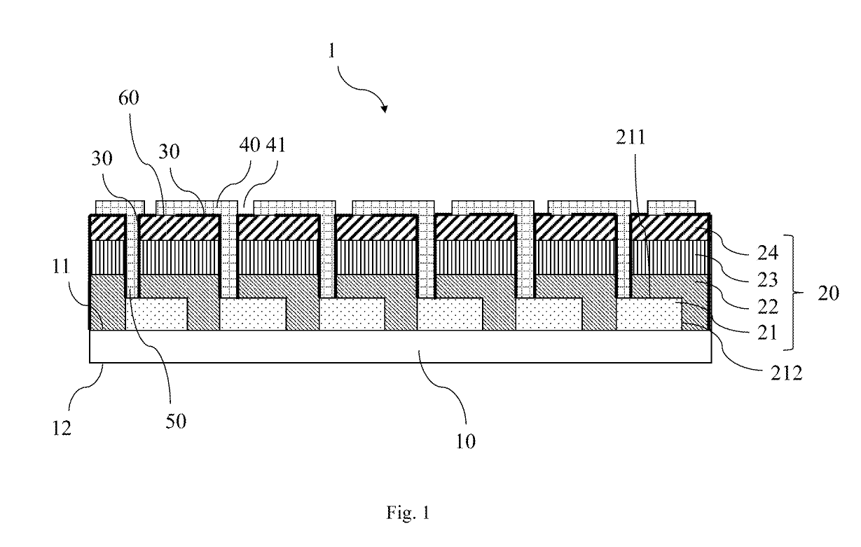

FIG. 1 illustrates a cross-section view of a perovskite solar cell module in accordance with one of the embodiments of the present invention. As shown, the perovskite solar cell module 1 includes a light-transparent substrate 10, a plurality of solar cells 20, a plurality of insulating units 30, and a plurality of connecting units 40.

The light-transparent substrate 10 has an upper surface 11 and a lower surface 12, where the light passes through. The solar cells 20 are formed on the light-transparent substrate 10. Each of the solar cells 20 is constituted by a transparent conductive layer 21, a first carrier conducting layer 22, a perovskite layer 23, and a second carrier conducting layer 24. The transparent conductive layer 21 is disposed on the upper surface 11 of the light-transparent substrate 10. The first carrier conducting layer 22 is disposed on the transparent conductive layer 21. The first carrier conducting layer 22 partially covers an upper surface 211 of the transparent conductive layer 21 and entirely covers the side surface 212 of the transparent conductive layer 21. The first carrier conducting layer 22 further contacts with the upper surface 11 of the light-transparent substrate 10. Moreover, the perovskite layer 23 is disposed on the first carrier conducting layer 22, while the second carrier conducting layer 24 is disposed on the perovskite layer 23. Although six solar cells 20 are demonstrated in FIG. 1, the invention does not limit to this number.

As shown, the insulating units 30 are disposed on the second carrier conducting layer 24 of each solar cell 20, and extend to cover the side surfaces of the second conducting layer 24, the perovskite layer 23 and the first carrier conducting layer 22 of each solar cell 20. The insulating units 30 form a first channel 50 with the upper space of the transparent conductive layer 21 of each solar cell 20, and form a second channel 60 with the upper space of the second carrier conducting layer 24 of each solar cell 20. Each of the first channels 50 is between two adjacent solar cells 20.

Each of the connecting units 40 is disposed above the second carrier conducting layer 24 of each solar cell 20. The connecting units 40 electrically connect one solar cell 20 to another through the first channel 50 and the second channel 60. Additionally, there remains a gap 41 between two adjacent connecting units 40.

In one embodiment, the transparent conductive layer 21 may be made of indium tin oxide (ITO) or fluorine-doped tin oxide (FTO).

The solar cells 20 may either be in a regular structure or an inverted structure. Thus, the first carrier conducting layer 22 may either be a hole conducting layer or an electron conducting layer; while the second carrier conducting layer 24 may either be an electron conducting layer or a hole conducting layer depending on the first carrier conducting layer 22. Simply put, assuming the first carrier conducting layer 22 is a hole conducting layer, the second carrier conducting layer 24 is then an electron conducting layer; and vice versa. In one embodiment, the hole conducting layer may be made of poly(3,4-ethylenedioxythiophene)/polystyrene sulfonate (PEDOT:PSS), Spiro-MeOTAD, cuprous thiocyanate (CuSCN), poly(3-hexylthiophene) (P3HT), nickel oxide, or cuprous oxide; the electron conducting layer may be made of fullerene (C₆₀), PC₆₁BM, ICBA, PC₇₁BM, zinc oxide (ZnO), titanium dioxide (TiO₂), tin dioxide (SnO₂), or tungsten trioxide (WO₃).

In one embodiment, the perovskite layer 23 is represented as ABC₃₋ₓDₓ. A is at least one of H₃CNH₃ ion, H₂NCH═NH₂ and/or cesium ion, B is at least one of lead ion, tin ion and/or germanium ion, C is at least one of chloride ion, bromide ion and/or iodide ion, while D is also at least one of chloride ion, bromide ion and/or iodide ion. Additionally, x is a real number ranging from 0 to 3.

In one embodiment, the light-transparent substrate 10 is either made of glass or sapphire.

In one embodiment, the connecting units 40 are made of aluminum, silver, gold or a combination thereof.

In one embodiment, the insulating units 30 are made of silicon dioxide (SiO₂) or silicon nitride (Si₃N₄).

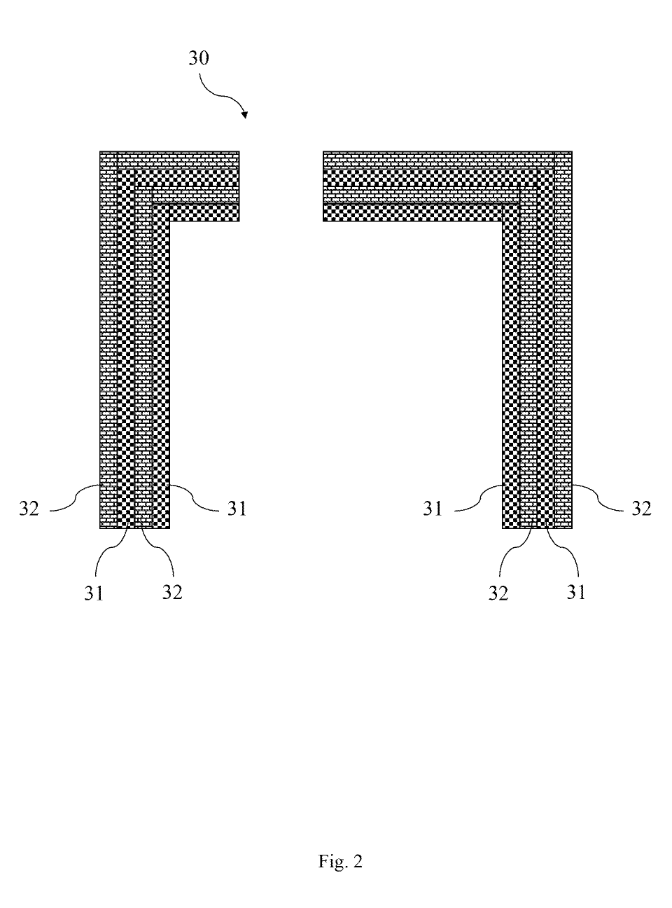

In one embodiment, the insulating units are in the structure of distributed Bragg reflection. FIG. 2 shows a cross-section view of the structure in accordance with the present invention. The structure includes a plurality of first refractive layers 31 and a plurality of second refractive layers 32 stacked interlacedly. It is noted that the refractive indexes of the first refractive layers 31 and the second refractive layers 32 differ. For instance, the first refractive layers 31 may be made of silicon dioxide (SiO₂) which refractive index is about 1.5; while the second refractive layer 32 may be titanium dioxide (TiO₂) which refractive index is 2.5.

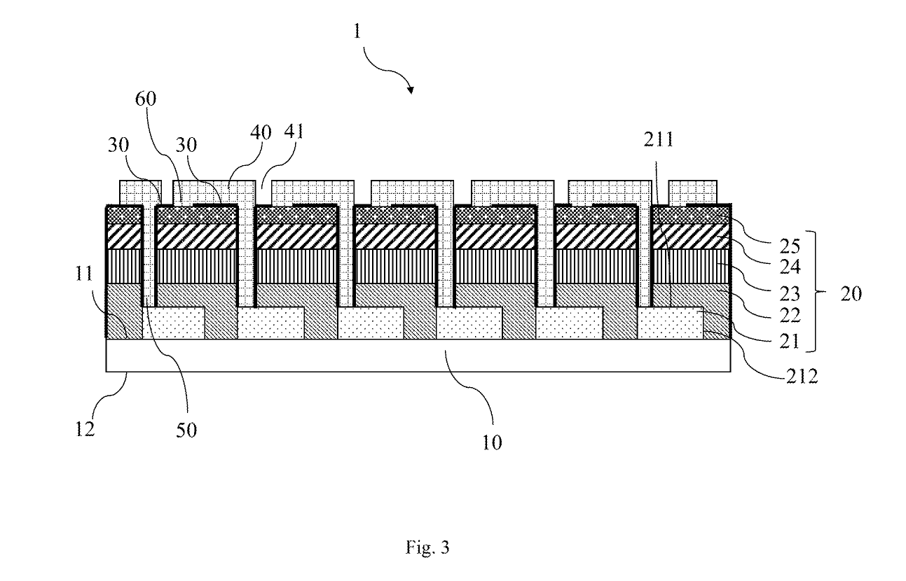

FIG. 3 shows a cross-section view of a perovskite solar cell module in accordance with another of the embodiments of the present invention. In this embodiment, each solar cell 20 in the perovskite solar cell module 1 further includes a carrier-blocking layer 25 disposed on the second carrier conducting layer 24. Additionally, each insulating unit 30 disposes on the carrier-blocking layer 25 and extensively covers the side surfaces of the carrier-blocking layer 25, the second carrier conducting layer 24, the perovskite layer 23 and the first carrier conducting layer 22. The insulating unit 30 and the upper space of the transparent conductive layer 21 of each solar cell 20 constitute a first channel 50. The insulating unit 30 and the upper space of the carrier-blocking layer 25 of each solar cell 20 further constitute a second channel 60. The carrier-blocking layer 25 may either be a hole-blocking layer or an electron-blocking layer. For instance and without limitation, assuming the second carrier conducting layer 24 is an electron conducting layer, the carrier-blocking layer 25 is then a hole-blocking layer for stopping holes from passing through while allowing electrons to pass and reach the connecting unit 40. The hole-blocking layer may be, for example and without limitation, bathocuproine (BCP). The rest components of the perovskite solar cell module 1 shown in FIG. 3 are similar to those previously discussed.

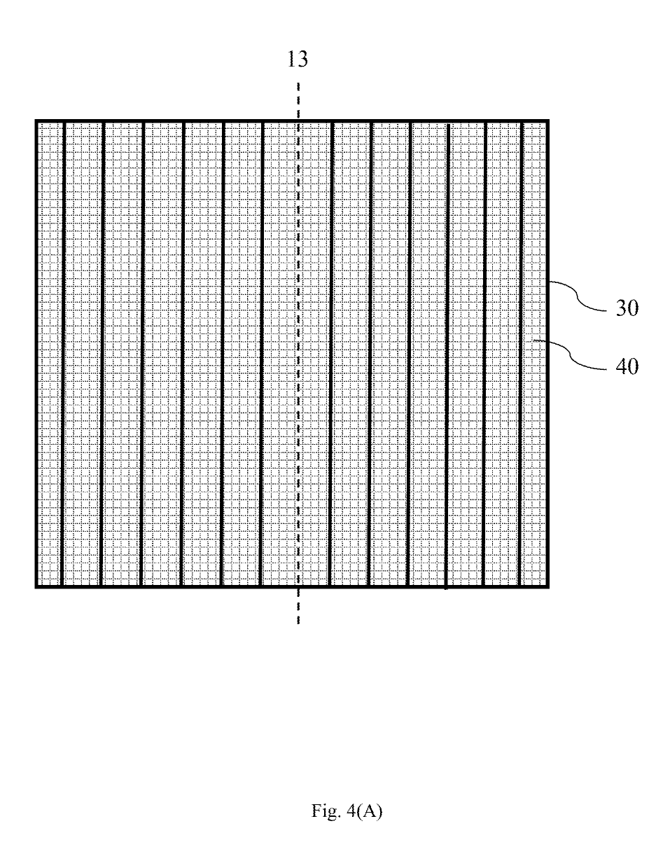

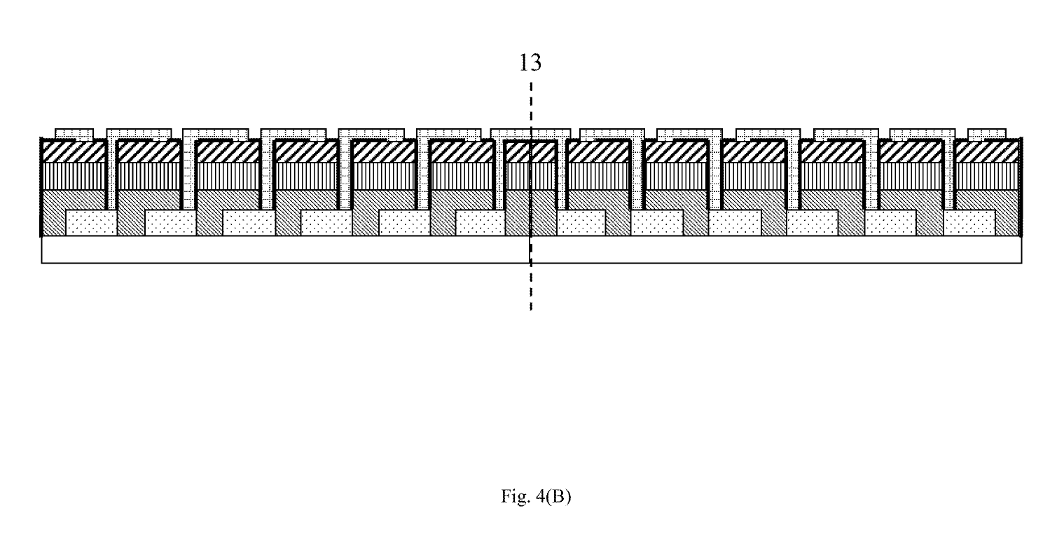

FIG. 4(A) and FIG. 4(B) respectively illustrate a top view and a cross-section view of a perovskite solar cell module 1 of the present invention. As shown, the solar cells 20 are arranged symmetrically in accordance with a virtual central-plane 13 in the light-transparent substrate 10.

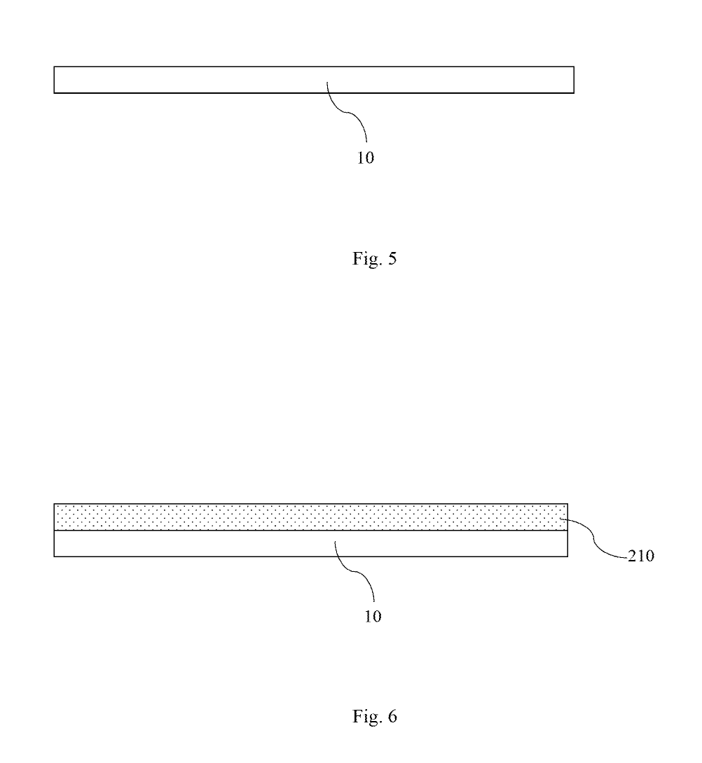

FIGS. 5 to 12 demonstrate the steps for preparing and manufacturing a perovskite solar cell module in accordance with the present invention. The steps are discussed as follows.

At Step 1, as shown in FIG. 5, providing a light-transparent substrate 10. In the present invention, a plurality of solar cells 20 can be formed on the light-transparent substrate 10 and electronically connected with each other to constitute the perovskite solar cell module 1.

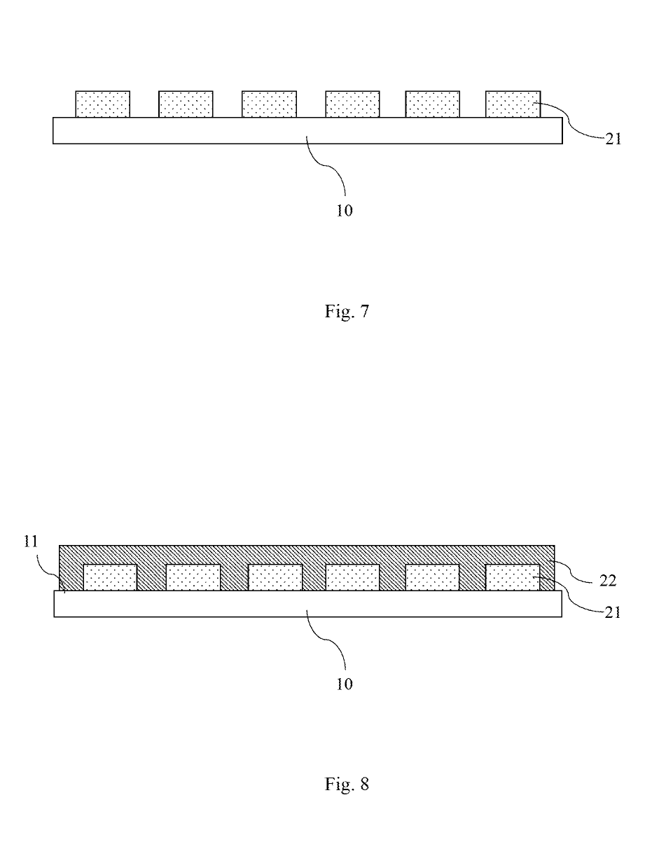

At Step 2, as shown in FIGS. 6 and 7, forming a plurality of transparent conductive layers 21 on the light-transparent substrate 10. The process may further include: depositing a transparent conductive film 210 on the light-transparent substrate 10 (see FIG. 6), and etching the transparent conductive film 210 to form the transparent conductive layers 21 (see FIG. 7). The deposit process may be completed by sputtering and E-beam evaporation. The transparent conductive film 210 may be made of indium tin oxide (ITO) or fluorine-doped tin oxide (FTO). The transparent conductive layers 21 may be patterned by wet-etching. In one example, assuming ITO is adopted as the transparent conductive layer, the solution chosen for etching may be 37% HCI (hydrochloric acid).

At Step 3, as shown in FIG. 8, forming a first carrier conducting layers 22 on the transparent conductive layers 21. The first carrier conducting layer 22 entirely covers the side surfaces of the transparent conductive layers 21. The first carrier conducting layer 22 further contacts with an upper surface 11 of the light-transparent substrate 10. The first carrier conducting layer 22 may either be a hole conducting layer or an electron conducting layer. Assuming it is a hole conducting layer, the first carrier conducting layer 22 may be made of poly(3,4-ethylenedioxythiophene)/polystyrene sulfonate (PEDOT:PSS), Spiro-MeOTAD, cuprous thiocyanate (CuSCN), poly(3-hexylthiophene) (P3HT), nickel oxide, or cuprous oxide. The process may further include: conducting an UV/ozone surface treatment to the transparent conductive layer 21 for around 30 minutes, spin-coating at 4000 rpm for about 60 seconds to deposit, say PEDOT:PSS, and heating the deposit at 150° C. for about 15 minutes.

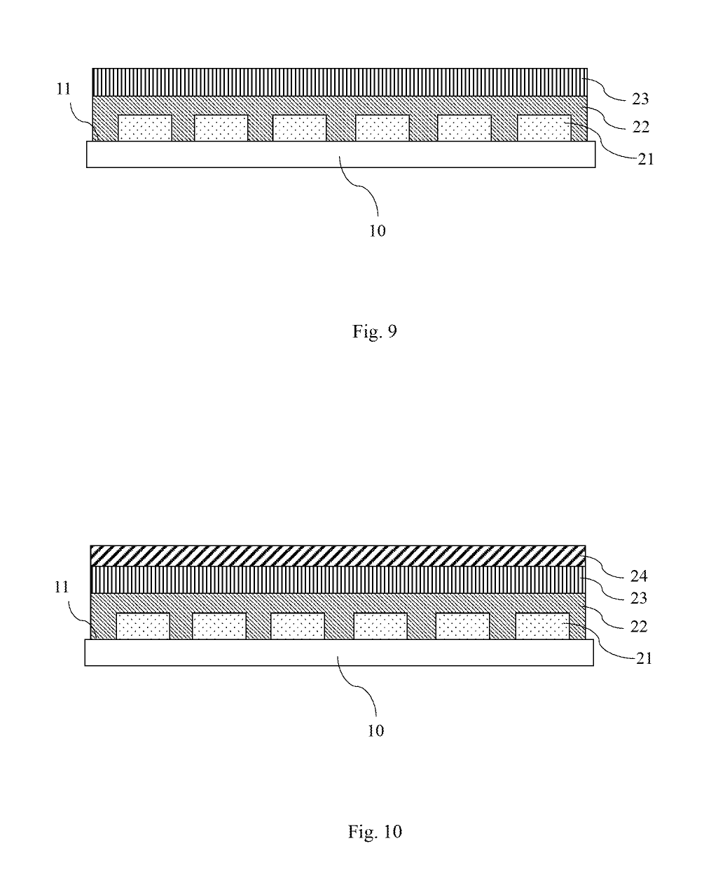

At Step 4, as shown in FIG. 9, forming a perovskite layer 23 on the first carrier conducting layer 22. The perovskite layer 23 is represented as ABC₃₋ₓDₓ, where A is at least one of H₃CNH₃ ion, H₂NCH═NH₂ and/or cesium ion, B is at least one of lead ion, tin ion and/or germanium ion, C is at least one of chloride ion, bromide ion and/or iodide ion, while D is also at least one of chloride ion, bromide ion and/or iodide ion. Additionally, x is a real number ranging from 0 to 3. In one example, assuming the perovskite layer is CH₃NH₃PbI₃, the process further includes: depositing a lead iodide (PbI₂) film onto the first carrier conducting layer 22; reacting methylammonium iodide (CH₃NH₃I) vapor with the PbI₂ film to form the perovskite layer 23. It should be noted that the thickness of the PbI₂ film is around 60 nm and it can be obtained by way of thermal evaporation. Additionally, the CH₃NH₃I vapor may be obtained by way of chemical vapor deposition. The CH₃NH₃I vapor is then reacted with the PbI₂ film at about 80° C. to obtain the perovskite layer 23.

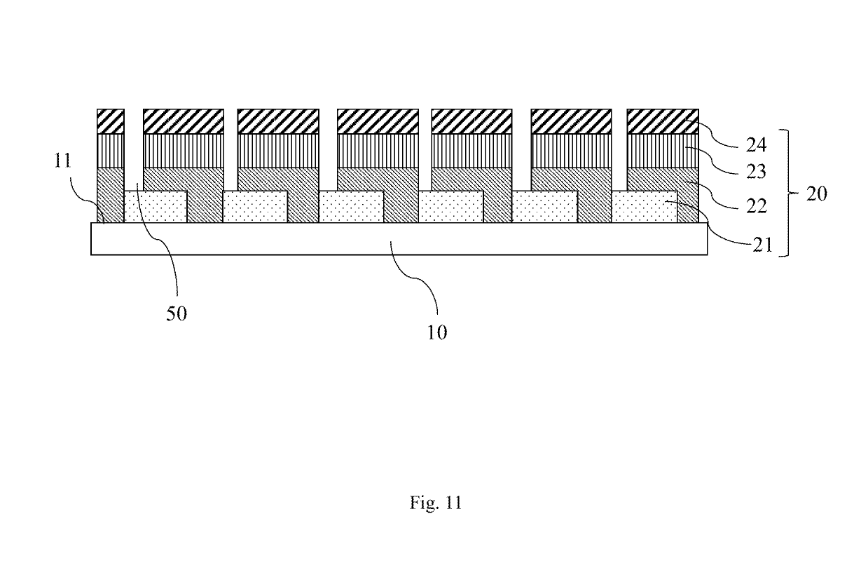

At Step 5, as shown in FIG. 10, forming a second carrier conducting layer 24 on the perovskite layer 23. The second carrier conducting layer 24 may either be a hole conducting layer or an electron conducting layer. Continuing to the example discussed in Step 3, assuming the first carrier conducting layer 22 is a hole conducting layer, the second conducting layer 24 is then an electron conducting layer made of fullerene (C₆₀), PC₆₁BM, ICBA, PC₇₁BM, zinc oxide (ZnO), titanium dioxide (TiO₂), tin dioxide (SnO₂), or tungsten trioxide (WO₃). In one example, the process further includes depositing, say C₆₀ onto the perovskite layer 23 where the thickness of the second carrier conducting layer 24 is about 60 nm.

At Step 6, as shown in FIG. 11, forming a plurality of first channels 50, each of them extends upwardly from the upper surface of the transparent conductive layer 21 to the second carrier conducting layer 24. The first channels 50 define and isolate the transparent conductive layer 21, the first carrier conducting layer 22, the perovskite layer 23 and the second carrier conducting layer 24 into a plurality of solar cells 20. The process can be made by dry etching through the use of inductively coupled plasma.

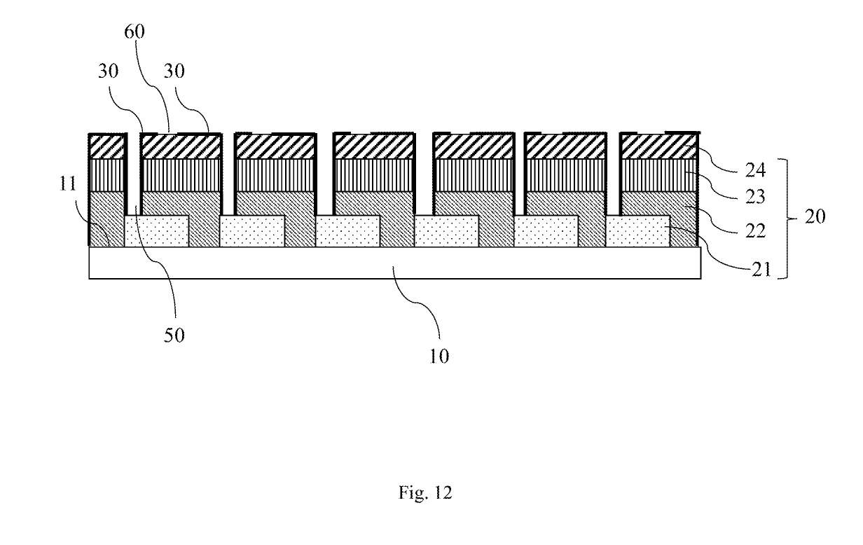

At Step 7, as shown in FIG. 12, forming a plurality of insulating units 30 on the second carrier conducting layer 24. For each solar cell 20, the insulating units 30 extend to cover the side surfaces of the second carrier conducting layer 24, the perovskite layer 23, and the first carrier conducting layer 22 within each of the first channels 50. The insulating units 30 further form a second channel 60 with the upper space of the second carrier conducting layer 24 of each solar cell 20. One may adopt a metal mask to deposit the insulating units 30 and form the second channel 60 by E-beam evaporation. The insulating units 30 may be made of silicon dioxide (SiO₂) or silicon nitride (Si₃N₄). In one embodiment, if it is SiO₂, the thickness is about 100 nm.

At Step 8, as shown in FIG. 1, forming a plurality of connecting units 40 above the second carrier conducting layer 24. The connecting units 40 electronically connect the solar cells 20 through the first channels 50 and the second channels 60, and there remains a gap 41 between two adjacent connecting units 40. The final product of the perovskite solar cell module 1 in accordance with the present invention is therefore obtained. One may adopt a metal mask to deposit an aluminum layer to form the connecting units 40 and the gaps 41 by way of thermal evaporation.

In one embodiment, the Step 7 may further include depositing a plurality of first refractive layers and a plurality of second refractive layers (not shown in the diagrams). The first refractive layers and the second refractive layers are stacked interlacedly; and their refractive indexes are different. The first refractive layers and the second refractive layers constitute the insulating units 30.

In one embodiment, as shown in FIG. 3, an additional layer—a carrier-blocking layer 25 may be formed right after the formation of the second carrier conducting layer 24 at Step 5. In such case, the insulating units 30 are formed on the carrier-blocking layer 25. Similarly, for each solar cell 20, the insulating units 30 extend to cover the side surfaces of the carrier-blocking layer 25, the second carrier conducting layer 24, the perovskite layer 23, and the first carrier conducting layer 22. The insulating units 30 further form a first channel 50 with the upper space of the transparent conductive layer 21 of each solar cell 20, and a second channel 60 with the upper space of the carrier-blocking layer 25 of each solar cell 20. The carrier-blocking layer 25 may either be a hole-blocking layer or an electron-blocking layer depending on the material of the second carrier conducting layer 24. For instance and without limitation, assuming the second carrier conducting layer 24 is an electron conducting layer, the carrier-blocking layer 25 is then a hole-blocking layer for stopping holes from passing through while allowing electrons to pass and reach the connecting units 40. The hole-blocking layer may be, for example and without limitation, bathocuproine (BCP).

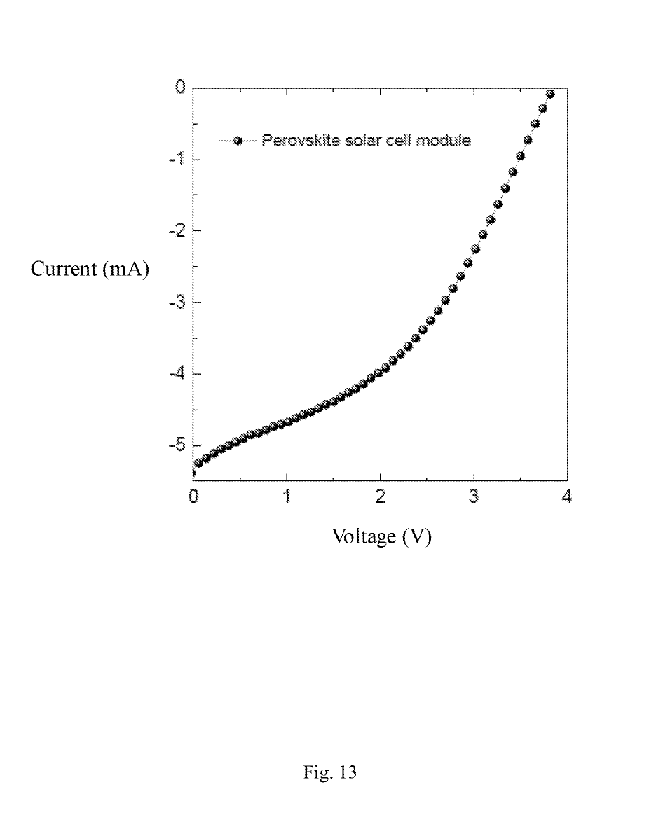

A reference is made to FIG. 13 where the experimental data of the perovskite solar cell module in accordance with the present invention is shown. The data is measured under the circumstance where the perovskite solar cell module is exposed to the light intensity of 100 mW/cm². It is obtained that the open circuit voltage (V_{oc}) is 3.85 V, the short circuit current (I_{sc}) is 5.34 mA, and the maximum output power (Pₘₐₓ) is 8.34 mW.

By changing the ratio of area where the light is harvested for the perovskite layer, the photon absorption in the present invention therefore increases. Additionally, by changing the relevant position of the transparent conductive layer and the first carrier conducting layer, it renders the side surface of the transparent conductive layer be entirely covered by the first carrier conducting layer; as a result, the usage of carriers is enhanced. The above two adoptions together further increase the efficiency of the module. Moreover, the insulating units are in the structure of distributed Bragg reflection and therefore can increase the photon absorption efficiency of the perovskite layer. Last but not least, the present invention further accomplishes the goal to manufacture a large-area perovskite solar cell module to meet the commercial demand.

The above-described embodiments of the invention are presented for purposes of illustration and not of limitation. Of course, those skilled in the art will recognize many modifications may be made to this configuration without departing from the scope of the disclosed aspects.

1. A perovskite solar cell module, comprising:
a light-transparent substrate having an upper surface and a lower surface where the light incidents through the lower surface;
a plurality of solar cells formed on the light-transparent substrate, each of the solar cells further comprises:
a transparent conductive layer disposed on the upper surface of the light-transparent substrate;
a first carrier conducting layer disposed on the transparent conductive layer, wherein the first carrier conducting layer partially covers an upper surface of the transparent conductive layer and entirely covers the side surface of the transparent conductive layer, wherein the first carrier conducting layer contacts with the upper surface of the light-transparent substrate;
a perovskite layer disposed on the first carrier conducting layer;
a second carrier conducting layer disposed on the perovskite layer;
a plurality of insulating units disposed on the second carrier conducting layer of each solar cell, wherein each insulating unit extends to cover the side surfaces of the second carrier conducting layer, the perovskite layer and the first carrier conducting layer of each solar cell, wherein the insulating units form a first channel with an upper space of the transparent conductive layer of each solar cell, and form a second channel with an upper space of the second carrier conducting layer of each solar cell; and
a plurality of connecting units disposed above the second carrier conducting layer of each solar cell, wherein each of the connecting units electronically connects one solar cell to another through the first channel and the second channel, wherein there remains a gap between two adjacent connecting units.

2. The perovskite solar cell module of claim 1, wherein the insulating units are distributed Bragg reflectors.

3. The perovskite solar cell module of claim 2, wherein each of the insulating units comprises a plurality of first refractive layers and a plurality of second refractive layers, wherein the first refractive layers and the second refractive layers are stacked interlacedly, and wherein the refractive indexes of the first and the second refractive layers differ.

4. The perovskite solar cell module of claim 1, wherein the material of the insulating units comprises silicon dioxide (SiO₂) or silicon nitride (Si₃N₄).

5. The perovskite solar cell module of claim 1, wherein the material of the light-transparent substrate comprises glass or sapphire.

6. The perovskite solar cell module of claim 1, wherein the material of the connecting units comprises aluminum, silver, gold or a combination thereof.

7. The perovskite solar cell module of claim 1, wherein the material of the transparent conductive layer comprises indium tin oxide (ITO) or fluorine-doped tin oxide (FTO).

8. The perovskite solar cell module of claim 1, wherein the first carrier conducting layer is either a hole conducting layer or an electron conducting layer; wherein the second carrier conducting layer is either an electron conducting layer or a hole conducting layer; wherein the material of the hole conducting layer comprises poly(3,4-ethylenedioxythiophene)/polystyrene sulfonate (PEDOT:PSS), Spiro-MeOTAD, cuprous thiocyanate (CuSCN), poly(3-hexylthiophene) (P3HT), nickel oxide, or cuprous oxide; wherein the material of the electron conducting layer comprises fullerene (C₆₀), PC61BM, ICBA, PC71BM, zinc oxide (ZnO), titanium dioxide (TiO₂), tin dioxide (SnO₂), or tungsten trioxide (WO₃).

9. The perovskite solar cell module of claim 1, the perovskite layer is represented as ABC3-xDx, wherein A is at least one of H₃CNH₃ ion, H₂NCH═NH₂ and/or cesium ion, B is at least one of lead ion, tin ion and/or germanium ion, C is at least one of chloride ion, bromide ion and/or iodide ion, while D is also at least one of chloride ion, bromide ion and/or iodide ion, wherein x is a real number ranging from 0 to 3.

10. The perovskite solar cell module of claim 1, wherein the solar cells are arranged symmetrically in accordance with a virtual central-plane of the light-transparent substrate.

11. A method of manufacturing a perovskite solar cell module having a plurality of solar cells, comprising:
providing a light-transparent substrate;
forming a plurality of transparent conductive layers on the light-transparent substrate;
forming a first carrier conducting layer on the transparent conductive layers, wherein the first carrier conducting layer covers the side surface of the transparent conductive layers entirely, wherein the first carrier conducting layer contacts with an upper surface of the light-transparent substrate;
forming a perovskite layer on the first carrier conducting layer;
forming a second carrier conducting layer on the perovskite layer;
forming a plurality of first channels, wherein each of the first channels extend upwardly from the upper surface of the transparent conductive layers to the second carrier conducting layer, wherein the first channels define and isolate the transparent conductive layer, the first carrier conducting layer, the perovskite layer and the second carrier conducting layer into the solar cells;
forming a plurality of insulating units on the second carrier conducting layer, wherein the insulating units extend to cover the side surfaces of the second carrier conducting layer, the perovskite layer, and the first carrier conducting layer within each of the first channels, wherein the insulating units further form a second channel with an upper space of the second carrier conducting layer of each solar cell; and
forming a plurality of connecting units above the second carrier conducting layer, the connecting units electronically connect one solar cell to another solar cell through the first channels and the second channels, wherein there remains a gap between two adjacent connecting units.

12. The method of claim 11 further comprising:
depositing a transparent conductive film on the light-transparent substrate; and
foliating the transparent conductive layers by etching the transparent conductive film.

13. The method of claim 11 further comprising:
depositing a plurality of first refractive layers; and
depositing a plurality of second refractive layers;
wherein the first refractive layers and the second refractive layers are stacked interlacedly, wherein the refractive index of the first refractive layers and that of the second refractive layers differ; and wherein the first refractive layers and the second refractive layers constitute the insulating unit.
